(19) United States
(12) Patent Application Publication
(10) Pub. No.: US 2024/0039533 A1
(43) Pub. Date: Feb. 1, 2024

(54) Superconducting Quantum Chip

(71) Applicant: Huawei Technologies Co., Ltd., Shenzhen (CN)

(72) Inventors: Junling Long, Shenzhen (CN); Peng Zhao, Shenzhen (CN)

(21) Appl. No.: 18/483,821

(22) Filed: Oct. 10, 2023

Related U.S. Application Data
(63) Continuation of application No. PCT/CN2022/090292, filed on Apr. 29, 2022.

(30) Foreign Application Priority Data
Apr. 30, 2021 (CN) 202110486361.1

(51) Int. Cl. H03K 17/92; G06N 10/20; G06N 10/40

(52) U.S. Cl. CPC H03K 17/92; G06N 10/20; G06N 10/40

(57) ABSTRACT

A superconducting quantum chip includes a coupler and a controller. The coupler is configured to couple a first superconducting bit circuit and a second superconducting bit circuit. A frequency response curve of the coupler includes at least one phase inversion point, and the phase inversion point includes a resonance point or a pole of the frequency response curve. The controller is configured to adjust the frequency response curve of the coupler, so that an odd quantity of phase inversion points is included between a bit frequency of the first superconducting bit circuit and a bit frequency of the second superconducting bit circuit. The controller further adjusts a frequency of the phase inversion point, so that an equivalent interaction of cross-resonance effect of the first superconducting bit circuit and the second superconducting bit circuit is zero.

### CROSS-REFERENCE TO RELATED APPLICATIONS

This application is a continuation application of International Patent Application No. PCT/CN2022/090292, filed on Apr. 29, 2022, which claims priority to Chinese Patent Application No. 202110486361.1, filed on Apr. 30, 2021, both of which are hereby incorporated by reference in their entireties.

### TECHNICAL FIELD

The present disclosure relates to quantum computing, and in particular, to a superconducting quantum chip.

### BACKGROUND

Quantum computing is a new computing method that is based on quantum mechanics and utilizes characteristics, including quantum superposition and entanglement. For specific problems, such as large number factorization and quantum chemistry simulation, the quantum computing has an advantage of exponential acceleration over classical computing. Superconducting quantum computing is a quantum computing solution based on a superconducting circuit. The superconducting circuit is a microwave circuit that includes basic components such as a capacitor, an inductor, a transmission line, and a Josephson junction. A quantum chip that includes a superconducting circuit works in an ultra-low temperature environment provided by a dilution refrigerator to implement superconductivity. A superconducting quantum circuit is highly compatible with existing integrated circuit technologies in terms of design, manufacturing, measurement, and the like. This helps implement a highly flexible design and control of energy levels and coupling of quantum bits, having a great potential for large-scale application.

In a superconducting quantum chip, fixed capacitive coupling or quantum bus coupling is usually used between bit circuits. Such type of design reduces complexity of the circuit and reduces a difficulty in superconducting circuit design and micro processing/nano processing. However, an expanded quantity of superconducting bits brings a larger circuit size. In such a coupling manner, coupling between bit circuits cannot be disabled, and crosstalk between the bit circuits causes many problems, for example, it is difficult to execute single-bit logic gates simultaneously, and operation fidelity of a two-bit logic gate is limited.

### SUMMARY

Embodiments of the present disclosure provide a superconducting quantum chip to disable coupling between bit circuits. This greatly reduces crosswalk between bits and has no obvious limitation on a spatial layout of a superconducting quantum chip circuit.

According to a first aspect, an embodiment of the present disclosure provides a superconducting quantum chip. The superconducting quantum chip includes a first superconducting bit circuit, a second superconducting bit circuit, a coupler, and a controller. The coupler is configured to couple the first superconducting bit circuit and the second superconducting bit circuit, a frequency response curve of the coupler includes at least one phase inversion point, and the phase inversion point includes a resonance point or a pole of the frequency response curve; the controller is configured to adjust the frequency response curve of the coupler, so that an odd quantity of phase inversion points are included between a bit frequency of the first superconducting bit circuit and a bit frequency of the second superconducting bit circuit; and the controller is further configured to further adjust a frequency of the phase inversion point, so that an equivalent interaction of cross-resonance effect of the first superconducting bit circuit and the second superconducting bit circuit is zero. In this way, coupling between the superconducting bit circuits is disabled, crosstalk between the superconducting bit circuits is greatly reduced, and there is no obvious limitation on a spatial layout between the superconducting bit circuits.

In a possible design of the first aspect, the controller includes a bias circuit, and adjusts the frequency response curve of the coupler based on a bias current or a bias voltage. Therefore, flexibility of system implementation is improved.

In another possible design of the first aspect, the coupler includes a first fixed coupling circuit, a second fixed coupling circuit, and an adjustable coupling circuit, where the first fixed coupling circuit is connected to the first superconducting bit circuit and the adjustable coupling circuit, the second fixed coupling circuit is connected to the second superconducting bit circuit and the adjustable coupling circuit, and the adjustable coupling circuit is configured to adjust the frequency response curve based on a control signal of the controller. Therefore, the flexibility of the system implementation is improved.

In another possible design of the first aspect, the first fixed coupling circuit and the second fixed coupling circuit each include a capacitor, the adjustable coupling circuit includes a superconducting quantum interference device (SQUID) and a capacitor that are connected in parallel, and an equivalent inductance value of the SQUID is adjusted by using a circuit bias line. Therefore, the flexibility of the system implementation is improved.

In another possible design of the first aspect, two ends of the adjustable coupling circuit each are grounded by using a capacitor, one end is coupled to the first superconducting bit circuit by using the first fixed coupling circuit, and the other end is coupled to the second superconducting bit circuit by using the second fixed coupling circuit. Therefore, the flexibility of the system implementation is improved.

In another possible design of the first aspect, two ends of the adjustable coupling circuit each are grounded by using a capacitor, and one end is coupled to the first superconducting bit circuit and the second superconducting bit circuit by using the first fixed coupling circuit and the second fixed coupling circuit respectively. Therefore, the flexibility of the system implementation is improved.

In another possible design of the first aspect, one end of the adjustable coupling circuit is grounded, and the other end is coupled to the first superconducting bit circuit and the second superconducting bit circuit by using the first fixed coupling circuit and the second fixed coupling circuit respectively. Therefore, the flexibility of the system implementation is improved.

In another possible design of the first aspect, the first fixed coupling circuit and the second fixed coupling circuit each include a capacitor, the adjustable coupling circuit includes a first transmission line, a SQUID, and a second transmission line that are connected in series, and an equivalent inductance value of the SQUID is adjusted by using a circuit bias line. Therefore, the flexibility of the system implementation is improved.

According to a second aspect, an embodiment of the present disclosure provides a superconducting quantum chip. The superconducting bit circuit includes a first superconducting bit circuit, a second superconducting bit circuit, a coupler, and a controller. A bit frequency of the first superconducting bit circuit is equal to a bit frequency of the second superconducting bit circuit; the coupler is configured to couple the first superconducting bit circuit and the second superconducting bit circuit and a frequency response curve of the coupler includes one pole; and the controller is configured to adjust the frequency response curve of the coupler, so that a frequency of the pole is equal to the equal bit frequencies. In this way, for a scenario in which the bit frequencies are the same, coupling between the superconducting bit circuits is disabled, crosstalk between the superconducting bit circuits is greatly reduced, and there is no obvious limitation on a spatial layout between the superconducting bit circuits.

In a possible design of the second aspect, the controller includes a bias circuit, and adjusts the frequency response curve of the coupler based on a bias current or a bias voltage. Therefore, flexibility of system implementation is improved.

In another possible design of the second aspect, the coupler includes a first fixed coupling circuit, a second fixed coupling circuit, and an adjustable coupling circuit, where the first fixed coupling circuit is connected to the first superconducting bit circuit and the adjustable coupling circuit, the second fixed coupling circuit is connected to the second superconducting bit circuit and the adjustable coupling circuit, and the adjustable coupling circuit is configured to adjust the frequency response curve based on a control signal of the controller. Therefore, the flexibility of the system implementation is improved.

In another possible design of the second aspect, the first fixed coupling circuit and the second fixed coupling circuit each include a capacitor, the adjustable coupling circuit includes a SQUID and a capacitor that are connected in parallel, and an equivalent inductance value of the SQUID is adjusted by using a circuit bias line. Therefore, the flexibility of the system implementation is improved.

In another possible design of the second aspect, two ends of the adjustable coupling circuit each are grounded by using a capacitor, one end is coupled to the first superconducting bit circuit by using the first fixed coupling circuit, and the other end is coupled to the second superconducting bit circuit by using the second fixed coupling circuit. Therefore, the flexibility of the system implementation is improved.

In another possible design of the second aspect, two ends of the adjustable coupling circuit each are grounded by using a capacitor, and one end is coupled to the first superconducting bit circuit and the second superconducting bit circuit by using the first fixed coupling circuit and the second fixed coupling circuit respectively. Therefore, the flexibility of the system implementation is improved.

According to a third aspect, an embodiment of the present disclosure provides a quantum computer. The quantum computer includes a dilution refrigerator, the foregoing superconducting quantum chip, and a measurement and control system.

According to the foregoing solution provided in embodiments of the present disclosure, the coupling between the superconducting bit circuits is disabled, the crosstalk between the superconducting bit circuits is greatly reduced, and there is no obvious limitation on the spatial layout between the superconducting bit circuits. In addition, an adjustable coupling circuit with a longer physical length may be designed to increase line arrangement space between the bit circuits. Embodiments of the present disclosure greatly improve scalability of an architecture and help further increase a quantity of bits integrated in the superconducting quantum chip.

### BRIEF DESCRIPTION OF DRAWINGS

FIG. 1 is a schematic diagram of a structure of a quantum computer system according to an embodiment of the present disclosure;

FIG. 2 is a schematic diagram of a structure of a superconducting quantum chip according to an embodiment of the present disclosure;

FIG. 3 is a schematic diagram of a structure of a coupling circuit between quantum bit circuits according to an embodiment of the present disclosure;

FIG. 4 is a schematic diagram of adjusting frequency response when two bit frequencies are the same according to an embodiment of the present disclosure;

FIG. 5 is a schematic diagram of adjusting frequency response when two bit frequencies are different according to an embodiment of the present disclosure;

FIG. 6 is a schematic diagram of a structure of a coupler circuit according to an embodiment of the present disclosure;

FIG. 7 is a schematic diagram of a frequency response curve of the coupler shown in FIG. 6 according to an embodiment of the present disclosure;

FIG. 8 is a schematic diagram of a structure of a coupler circuit according to an embodiment of the present disclosure;

FIG. 9 is a schematic diagram of a frequency response curve of the coupler shown in FIG. 8 according to an embodiment of the present disclosure;

FIG. 10 is a schematic diagram of a structure of a coupler circuit according to an embodiment of the present disclosure;

FIG. 11 is a schematic diagram of a frequency response curve of the coupler shown in FIG. 10 according to an embodiment of the present disclosure;

FIG. 12 is a schematic diagram of a structure of a coupler circuit according to an embodiment of the present disclosure; and

FIG. 13 is a schematic diagram of a frequency response curve of the coupler shown in FIG. 12 according to an embodiment of the present disclosure.

### DESCRIPTION OF EMBODIMENTS

To make objectives, technical solutions, and advantages of the present disclosure clearer, the following further describes the implementations of the present disclosure in detail with reference to the accompanying drawings.

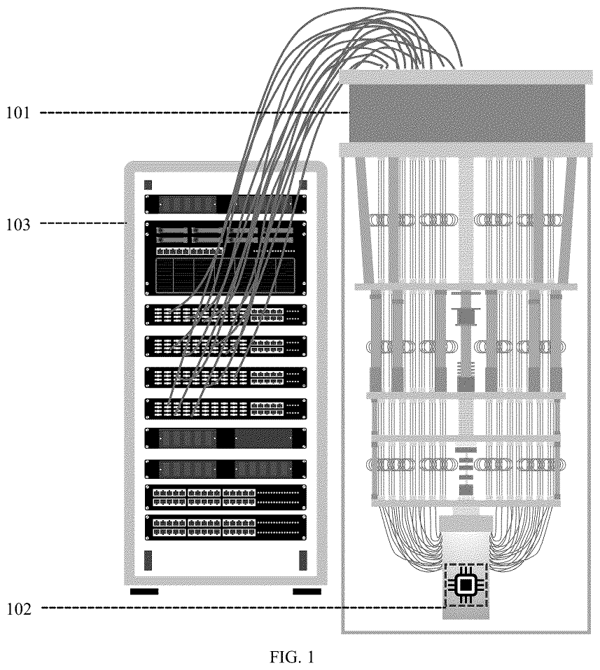

An embodiment of the present disclosure provides a quantum computer. A system structure of the quantum computer is shown in FIG. 1. The quantum computer includes a dilution refrigerator 101 configured to provide a low-temperature environment, a superconducting quantum chip 102 configured to implement a quantum computation information carrier, and a measurement and control system 103 configured to control a quantum bit status to perform a computation operation and read the quantum bit status.

The superconducting quantum chip is placed in the low-temperature environment. The measurement and control system controls a microwave source and modulates a pulse signal based on a computation operation requirement, and inputs a series of microwave pulse sequences to the superconducting quantum chip to perform an operation on a bit quantum state. After all operations are completed, the measurement and control system outputs a measurement pulse signal to the superconducting quantum chip, and obtains quantum bit status information by using a returned signal to obtain a computation result.

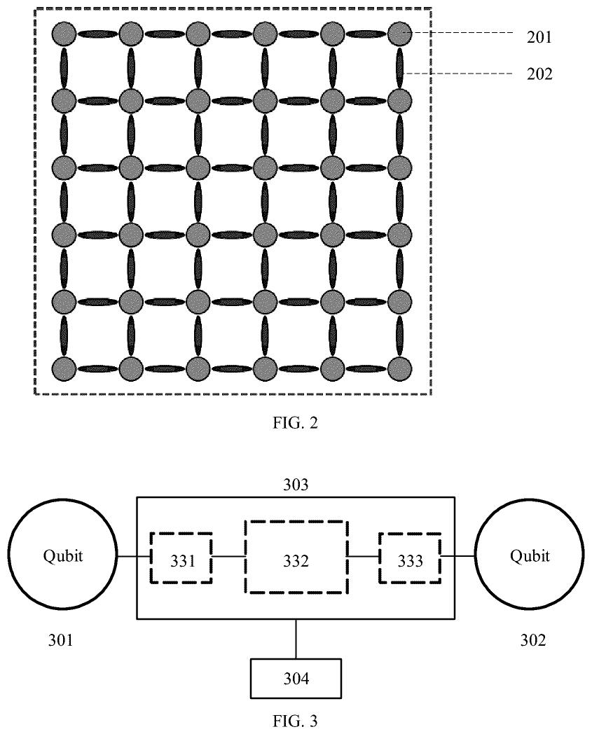

As shown in FIG. 2, a superconducting quantum chip is provided according to an embodiment of the present disclosure. The superconducting quantum chip includes superconducting bit circuits 201 of a two-dimensional array arrangement and couplers 202 that couple superconducting bit circuits. The two-dimensional array arrangement is a currently most promising bit arrangement structure for quantum error-correcting codes which include surface codes. To implement surface code error correction on a chip of a two-dimensional array arrangement, an error of a two-bit logic gate needs to be less than 1%. However, when a quantity of bits increases, a series of problems occur in the superconducting quantum chip. First, crosstalk between bits leads to a difficulty in calibrating a logic gate and an increased error. Second, a quantity of control lines increases proportionally with the quantity of bits, which makes it difficult to arrange the control lines.

As shown in FIG. 3, a circuit structure is provided according to an embodiment of the present disclosure. Two superconducting bit circuits 301 and 302 are coupled by using a coupler 303. The coupler 303 is controlled by a controller 304. An implementation of the coupler 303 includes a fixed coupling circuit 331, an adjustable coupling circuit 332, and a fixed coupling circuit 333, to couple the two superconducting bit circuits 301 and 302. The circuit structure shown in FIG. 3 is not only applicable to the two-dimensional array of bits arranged horizontally and vertically shown in FIG. 2, but also applicable to any arrangement manner.

The two fixed coupling circuits 331 and 333 may be fixed capacitors, inductors, transmission lines, or circuit networks that include combinations of capacitors, inductors, and transmission lines. The adjustable coupling circuit may include a capacitor, an inductor, a transmission line, or a circuit network that includes a combination of a capacitor, an inductor, and a transmission line, and an adjustable inductor or capacitor. For example, a SQUID is a loop device that includes two Josephson junctions connected in parallel, and is usually used as an adjustable inductor. An inductance of the SQUID may be changed by changing a magnetic flux in a SQUID loop.

Some inductors or capacitors in the coupling circuit are adjusted by using a control signal, for example, a current or a voltage, to change an S21 S-parameter frequency response curve of the entire coupler 303, so that a frequency of a resonance point (mode) or a pole (pole) in the frequency response curve is adjusted. Herein, the resonance point is a frequency whose attenuation dB approaches zero in the S21 frequency response curve of the circuit, and the pole is a frequency whose attenuation dB approaches negative infinity in the S21 frequency response curve of the circuit. On the S21 frequency response curve, a phase of S21 is reversed when the resonance point or the pole is passed. The resonance point and the pole are collectively referred to as phase inversion points.

Movement of the resonance point or the pole of the frequency response curve changes coupling between the two superconducting bit circuits, so that the coupling is disabled, or the coupling is enabled and adjusted. Based on different relationships between bit frequencies of the two superconducting bit circuits, two cases are described below.

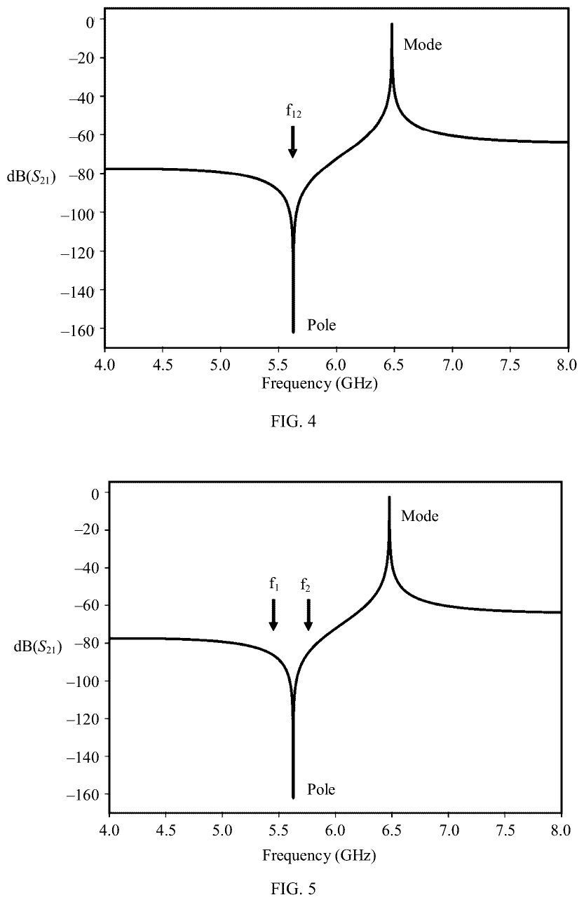

As shown in FIG. 4, when the bit frequencies of the two superconducting bit circuits 301 and 302 are the same, for example, both are equal to frequency f12, the frequency response curve may be adjusted by using the control signal. When the pole of the coupler is adjusted to frequency f12, the coupling between the two superconducting bit circuits is disabled. The coupling between the two superconducting bit circuits may be enabled by adjusting the pole to move away from frequency f12 by using the control signal. When the pole is on different sides of frequency f12, coupling symbols between the bit circuits are opposite. In addition, as the pole move away from f12, the coupling becomes stronger.

As shown in FIG. 5, when a bit frequency f1 (for example, in gigahertz (GHz)) of the superconducting bit circuit 301 is different from a bit frequency f2 of the superconducting bit circuit 302, to disable the coupling, the resonance point or the pole needs to be adjusted between frequency f1 and frequency f2, and a total quantity of phase inversion points (including the resonance point and the pole) between frequency f1 and frequency f2 is odd. Based on this, a frequency for disabling the coupling may be found by further fine-tuning frequencies of the resonance point and the pole, and the coupling may be enabled and coupling strength may be adjusted by moving away from the frequency. In an example, the coupling strength between the two superconducting bit circuits may be determined based on cross-resonance effect of the two superconducting bit circuits. In a process of fine-tuning the resonance point and the pole, an equivalent interaction of the cross-resonance effect of the two superconducting bit circuits needs to be measured. When a measured equivalent interaction is 0, the coupling between the two superconducting bit circuits is disabled.

According to the foregoing solution provided in embodiments of the present disclosure, the coupling between the superconducting bit circuits is disabled, the crosstalk between the superconducting bit circuits is greatly reduced, and there is no obvious limitation on the spatial layout between the superconducting bit circuits. In addition, an adjustable coupling circuit with a longer physical length may be designed to increase line arrangement space between the bit circuits.

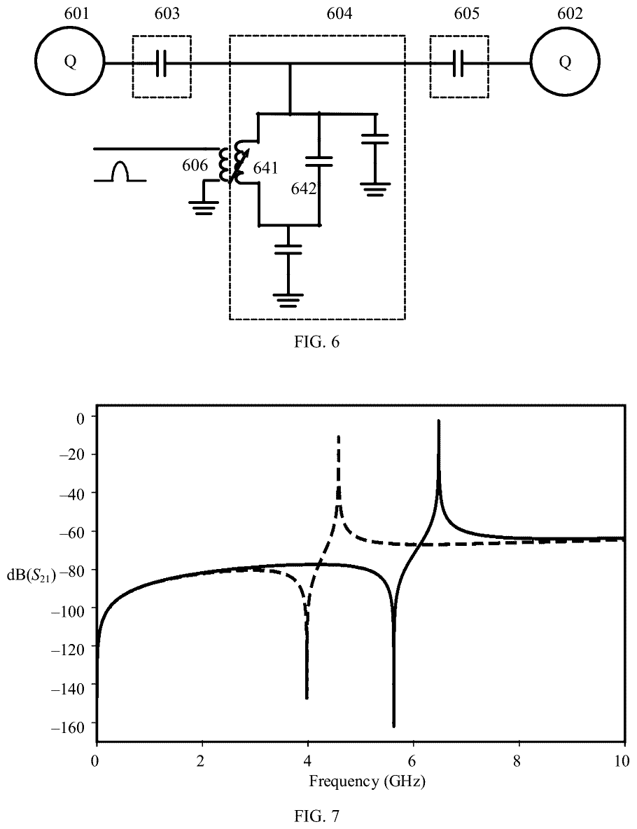

As shown in FIG. 6, a structure of another coupler is provided according to an embodiment of the present disclosure. The coupler includes a first fixed coupling circuit 603, an adjustable coupling circuit 604, and a second fixed coupling circuit 605. The fixed coupling circuits 603 and 605 are coupling capacitors. The adjustable coupling circuit 604 includes an adjustable inductor 641 and a capacitor 642 that are connected in parallel, and two ends of the adjustable coupling circuit 604 each are grounded by using a capacitor. The adjustable coupling circuit 604 may be referred to as a floating adjustable coupling circuit. The adjustable inductor 641 may be implemented by using a SQUID, and an inductance of the SQUID may be changed by changing a magnetic flux in a SQUID loop. A controller 606 may be implemented by loading a control signal onto a current bias line that is inductively coupled to the SQUID. Changing a bias current may change the inductance of the SQUID. A same end of the adjustable coupling circuit 604 at which the adjustable inductor 641 and the capacitor 642 are connected in parallel is coupled to the two superconducting bit circuits by using the first fixed coupling circuit 603 and the second fixed coupling circuit 605 respectively.

Usually, a capacitance of the fixed coupling circuit is about 1 femtofarad (fF) to 20 fF. A capacitance in the adjustable coupling circuit is about 20 fF to 200 fF. The inductance of the SQUID is about 0.1 nanohenry (nH) to 30 nH.

FIG. 7 is a graph of a frequency response curve of the coupler shown in FIG. 6. The frequency response curve includes a resonance point and a pole, and a frequency of the pole is less than a frequency of the resonance point. The frequency response curve may be changed by adjusting a bias current. A solid line and a dashed line in FIG. 7 correspond to different bias currents. The bias current is adjusted to control positions of the resonance point and the pole, so that the coupling is disabled or the coupling is enabled and adjusted.

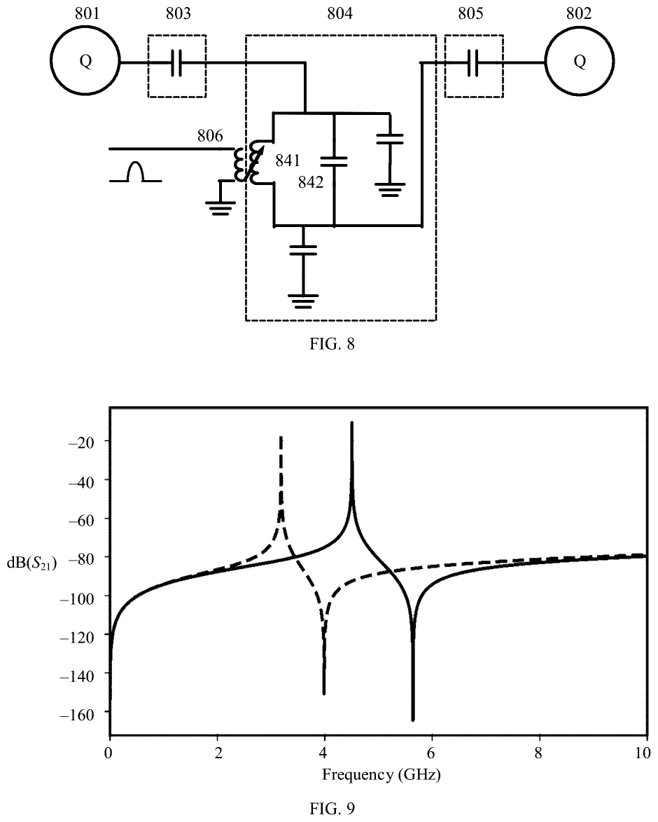

As shown in FIG. 8, a structure of another coupler is provided according to an embodiment of the present disclosure. A difference between the embodiment and the embodiment shown in FIG. 6 lies in that two ends of the adjustable coupling circuit 804 at which an adjustable inductor 841 and a capacitor 842 are connected in parallel are coupled to two superconducting bit circuits respectively by using a first fixed coupling circuit 803 and a second fixed coupling circuit 805. Similarly, a controller 806 may be implemented by loading a control signal onto a current bias line that is inductively coupled to a SQUID. Changing a bias current may change an inductance of the SQUID.

FIG. 9 is a graph of a frequency response curve of the coupler shown in FIG. 8. The frequency response curve also includes a resonance point and a pole, and a frequency of the pole is greater than a frequency of the resonance point. The frequency response curve may be changed by adjusting a bias current. A solid line and a dashed line in FIG. 9 correspond to different bias currents.

In the embodiments shown in FIG. 6 and FIG. 8, the coupling is disabled between the superconducting bit circuits, crosstalk between the superconducting bit circuits is greatly reduced, and there is no obvious limitation on a spatial layout between the superconducting bit circuits. In addition, in a chip layout design, a bit interval is allowed to be extended, so that a line arrangement space between bits is increased. The floating adjustable coupling circuit includes a resonance point and a pole. A frequency interval between the two superconducting circuits is usually not large. Therefore, the foregoing embodiments are applicable to a case in which bit frequencies of the two superconducting bit circuits are the same, or are applicable to a case in which bit frequencies of the two superconducting bit circuits are similar. The foregoing embodiments may be used to implement a logic gate of fermionic simulation, or implement an adiabatic controlled-phase gate operation. The two coupling cases in FIG. 6 and FIG. 8 may be flexibly selected to avoid a frequency congestion problem.

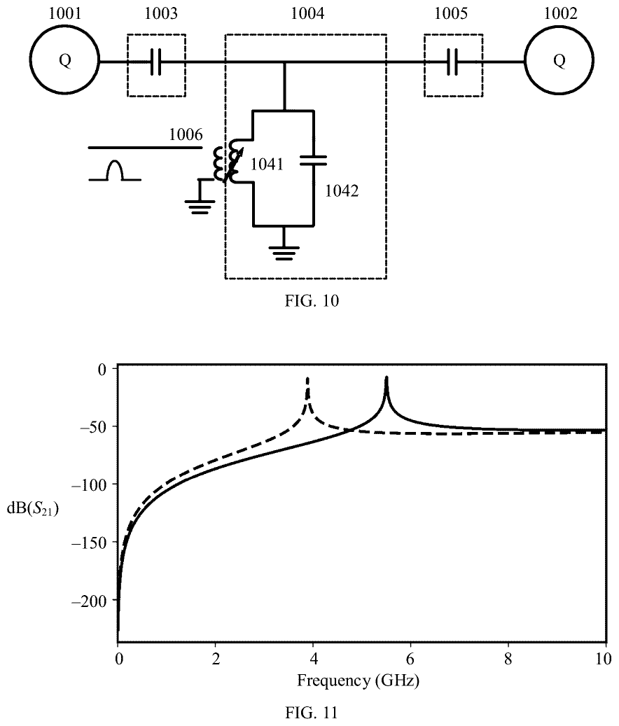

As shown in FIG. 10, a coupler structure is further provided according to an embodiment of the present disclosure. The coupler includes a first fixed coupling circuit 1003, an adjustable coupling circuit 1004, and a second fixed coupling circuit 1005. The fixed coupling circuits 1003 and 1005 are coupling capacitors. The adjustable coupling circuit 1004 includes an adjustable inductor 1041 and a capacitor 1042 that are connected in parallel. One end of the adjustable coupling circuit 1004 is directly grounded, and the other end of the adjustable coupling circuit 1004 is coupled to the two superconducting bit circuits by using the first fixed coupling circuit 1003 and the second fixed coupling circuit 1005 respectively. Similarly, the adjustable inductor 1041 may be implemented by using a SQUID, and an inductance of the SQUID may be changed by changing a magnetic flux in a SQUID loop. A controller 1006 may be implemented by loading a control signal onto a current bias line that is inductively coupled to the SQUID. Changing a bias current may change the inductance of the SQUID.

Usually, a capacitance of the fixed coupling circuit is about 1 fF to 20 fF. A capacitance in the adjustable coupling circuit is about 20 fF to 200 fF. The inductance of the SQUID is about 0.1 nH to 30 nH.

FIG. 11 is a graph of a frequency response curve of the coupler shown in FIG. 10. The frequency response curve includes a resonance point. The frequency response curve may be changed by adjusting a bias current. A solid line and a dashed line in FIG. 11 correspond to different bias currents. The bias current is adjusted, to control a position of the resonance point, so that the coupling is disabled or the coupling is enabled and adjusted.

In the embodiment shown in FIG. 10, the coupling between the superconducting bit circuits is tuned off, crosstalk between the superconducting bit circuits is greatly reduced, and there is no obvious limitation on a spatial layout between the superconducting bit circuits. In addition, in a chip layout design, a bit interval is allowed to be extended, so that a line arrangement space between bits is increased. It can be learned from FIG. 11 that the frequency response curve of the coupler in FIG. 10 includes only one resonance point. To prevent quantum information in the superconducting bit circuit from leaking to the coupler, the embodiment shown is usually applicable to a case in which a bit frequency difference between the two superconducting bit circuits is relatively large. The adjustable coupling circuit may be used to implement a more flexible two-bit logic gate: a parametric gate. Because the difference between the two bit frequencies is relatively large, a driving frequency of the parametric gate of the adjustable coupling circuit is higher, so that interaction of other spurious parameters is avoided. Therefore, an operation speed of the parametric gate may be greatly improved.

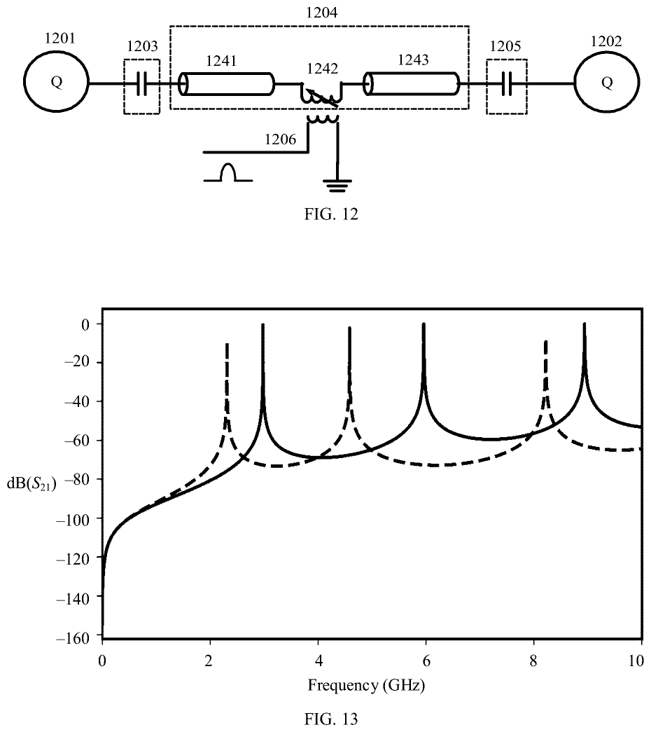

As shown in FIG. 12, a coupler structure is further provided according to an embodiment of the present disclosure. The coupler includes a first fixed coupling circuit 1203, an adjustable coupling circuit 1204, and a second fixed coupling circuit 1205. The fixed coupling circuits 1203 and 1205 are coupling capacitors, and the adjustable coupling circuit 1204 includes a transmission line 1241, an adjustable inductor 1242, and a transmission line 1243 that are connected in series. Lengths of the two transmission lines may be different. Similarly, the adjustable inductor 1242 may be implemented by using a SQUID, and an inductance of the SQUID may be changed by changing a magnetic flux in a SQUID loop. A controller 1206 may be implemented by loading a control signal onto a current bias line that is inductively coupled to the SQUID. Changing a bias current may change the inductance of the SQUID.

Usually, a capacitance of the fixed coupling circuit is about 1 fF to 20 fF. A length of the transmission line in the adjustable coupling circuit is about 1 mm to 100 mm. The inductance of the SQUID is about 0.1 nH to 30 nH.

FIG. 13 is a graph of a frequency response curve of the coupler shown in FIG. 12. The frequency response curve includes a plurality of resonance points. The frequency response curve may be changed by adjusting a bias current. A solid line and a dashed line in FIG. 13 correspond to different bias currents. The bias current is adjusted to control a position of the resonance point, so that the coupling is disabled or the coupling is enabled and adjusted. A quantity of resonance points is related to the transmission line, and lengths of the two transmission lines may be designed longer, so that more resonance points are generated on the frequency response curve.

In the embodiment shown in FIG. 12, the coupling between the superconducting bit circuits is tuned off, crosstalk between the superconducting bit circuits is greatly reduced, and there is no obvious limitation on a spatial layout between the superconducting bit circuits. In addition, in a chip layout design, a bit interval is allowed to be extended, so that a line arrangement space between bits is increased.

It can be learned from FIG. 13 that the frequency response curve of the coupler in FIG. 12 includes a plurality of resonance points. To prevent quantum information in the superconducting bit circuit from leaking to these different resonance points, the embodiment shown is applicable to a case in which a bit frequency difference between the two superconducting bit circuits is relatively large. Usually, the bit frequencies of the two superconducting bit circuits are required to be far away from all the resonance points. To disable the coupling, an odd quantity of resonance points are required between the bit frequencies of the two superconducting bit circuits. The adjustable coupling circuit may be used to implement a more flexible two-bit logic gate: a parametric gate. Because the difference between the two bit frequencies is relatively large, a driving frequency of the parametric gate of the adjustable coupling circuit is higher, so that interaction of other spurious parameters is avoided. Therefore, an operation speed of the parametric gate may be greatly improved, so that a fast parametric gate is implemented.

Compared with the embodiment shown in FIG. 10, the embodiment shown in FIG. 12 can make an interval between the bit frequencies farther. Because the resonance point of coupler in FIG. 10 may be very low, correspondingly, a length of the coupler is very long, and is applicable to long-range coupling between bit circuits. For example, the embodiment shown in FIG. 12 may be used to perform long-range coupling on different bit chips, so that small bit chips are combined to obtain a larger-scale quantum processor, and a quantity of bits of the quantum processor expands from hundreds to thousands or even millions.

Although the present disclosure is described herein with reference to embodiments, in a process of implementing the present disclosure, a person skilled in the art may understand and implement another variation of the disclosed embodiments by viewing the accompanying drawings, disclosed content, and the appended claims. In the claims, the word “comprising” does not exclude another component or another step, and “a” or “one” does not exclude a case of a plurality of objects.

Although the present disclosure is described with reference to features and embodiments thereof, it is clear that various modifications and combinations may be made to them. Correspondingly, this specification and accompanying drawings are merely example description of the present disclosure defined by the accompanying claims, and are considered as any of or all modifications, variations, combinations or equivalents that cover the scope of the present disclosure. It is clearly that a person skilled in the art can make various modifications and variations to the present disclosure without departing from the scope of the present disclosure. The present disclosure is intended to cover these modifications and variations of the present disclosure provided that they fall within the scope of protection defined by the following claims and their equivalent technologies.

What is claimed is:

1. A superconducting quantum chip, comprising:
a first superconducting bit circuit;
a second superconducting bit circuit;
a coupler configured to:
couple the first superconducting bit circuit and the second superconducting bit circuit; and
produce a frequency response curve comprising at least one phase inversion point, wherein the phase inversion point comprises a resonance point or a pole of the frequency response curve; and
a controller configured to:
adjust the frequency response curve to obtain an odd quantity of phase inversion points between a first bit frequency of the first superconducting bit circuit and a second bit frequency of the second superconducting bit circuit; and
adjust a frequency of the at least one phase inversion point for obtaining an equivalent interaction of cross-resonance effect of the first superconducting bit circuit and the second superconducting bit circuit as zero.

2. The superconducting quantum chip of claim 1, wherein the controller comprises a bias circuit, and wherein the controller is further configured to adjust the frequency response curve based on a bias current or a bias voltage of the bias circuit.

3. The superconducting quantum chip of claim 1, wherein the controller is configured to output a control signal, and wherein the coupler comprises:
an adjustable coupling circuit configured to adjust the frequency response curve based on the control signal;
a first fixed coupling circuit connected to the first superconducting bit circuit and the adjustable coupling circuit; and
a second fixed coupling circuit connected to the second superconducting bit circuit and the adjustable coupling circuit.

4. The superconducting quantum chip of claim 3, wherein the first fixed coupling circuit comprises a first capacitor, wherein the second fixed coupling circuit comprises a second capacitor, wherein the adjustable coupling circuit comprises a superconducting quantum interference device (SQUID) and a third capacitor, wherein the SQUID is connected in parallel to the third capacitor, and wherein the SQUID is configured to produce an equivalent inductance value that is adjustable using a circuit bias line.

5. The superconducting quantum chip of claim 4, wherein the adjustable coupling circuit comprises two ends and a capacitor, wherein each of the two ends is grounded using the capacitor, wherein a first end of the two ends is coupled to the first superconducting bit circuit using the first fixed coupling circuit, and wherein a second end of the two ends is coupled to the second superconducting bit circuit using the second fixed coupling circuit.

6. The superconducting quantum chip of claim 4, wherein the adjustable coupling circuit comprises two ends and a capacitor, wherein the two ends are grounded using the capacitor, and wherein one end of the two ends is coupled to the first superconducting bit circuit using the first fixed coupling circuit and to the second superconducting bit circuit using the second fixed coupling circuit.

7. The superconducting quantum chip of claim 4, wherein the adjustable coupling circuit comprises two ends, wherein a first end of the two ends is grounded, and wherein a second end of the two ends is coupled to the first superconducting bit circuit using the first fixed coupling circuit and to the second superconducting bit circuit using the second fixed coupling circuit.

8. The superconducting quantum chip of claim 3, wherein the first fixed coupling circuit comprises a first capacitor, wherein the second fixed coupling circuit comprises a second capacitor, wherein the adjustable coupling circuit comprises a series connection of a first transmission line, a superconducting quantum interference device (SQUID), and a second transmission line, and wherein the SQUID is configured to produce an equivalent inductance value that is adjusted using a circuit bias line.

9. A superconducting quantum chip, comprising:
a first superconducting bit circuit comprising a bit frequency;
a second superconducting bit circuit comprising the bit frequency;
a coupler configured to:
couple the first superconducting bit circuit to the second superconducting bit circuit; and
produce a frequency response curve comprising one pole; and
a controller configured to adjust the frequency response curve to obtain a frequency of the pole that is equal to the bit frequency.

10. The superconducting quantum chip of claim 9, wherein the controller comprises a bias circuit, and wherein the controller is further configured to adjust the frequency response curve based on a bias current or a bias voltage.

11. The superconducting quantum chip of claim 9, wherein the coupler comprises:
an adjustable coupling circuit configured to adjust the frequency response curve based on a control signal of the controller;
a first fixed coupling circuit connected to the first superconducting bit circuit and the adjustable coupling circuit; and
a second fixed coupling circuit connected to the second superconducting bit circuit and the adjustable coupling circuit.

12. The superconducting quantum chip of claim 11, wherein the first fixed coupling circuit comprises a first capacitor, wherein the second fixed coupling circuit comprises a second capacitor, wherein the adjustable coupling circuit comprises a superconducting quantum interference device (SQUID) and a third capacitor, wherein the SQUID is connected in parallel to the third capacitor, and wherein the SQUID is configured to produce an equivalent inductance value that is adjustable using a circuit bias line.

13. The superconducting quantum chip of claim 12, wherein the adjustable coupling circuit comprises two ends and a capacitor, wherein each of the two ends is grounded using the capacitor, wherein a first end of the two ends is coupled to the first superconducting bit circuit using the first fixed coupling circuit, and wherein a second end of the two ends is coupled to the second superconducting bit circuit using the second fixed coupling circuit.

14. The superconducting quantum chip of claim 12, wherein the adjustable coupling circuit comprises two ends and a capacitor, wherein each of the two ends is grounded using the capacitor, and wherein one end of the two ends is coupled to the first superconducting bit circuit using the first fixed coupling circuit and to the second superconducting bit circuit using the second fixed coupling circuit.

15. A quantum computer, comprising:
a dilution refrigerator configured to provide a low-temperature environment;
a measurement and control system; and
a superconducting quantum chip configured to operate in the low-temperature environment, wherein the superconducting quantum chip comprises:
a first superconducting bit circuit;
a second superconducting bit circuit;
a coupler configured to couple the first superconducting bit circuit and the second superconducting bit circuit; and
produce a frequency response curve comprising at least one phase inversion point, wherein the phase inversion point comprises a resonance point or a pole of the frequency response curve; and
a controller configured to:
adjust the frequency response curve o to obtain an odd quantity of phase inversion points between a first bit frequency of the first superconducting bit circuit and a second bit frequency of the second superconducting bit circuit; and
adjust a frequency of the phase inversion point to obtain an equivalent interaction of cross-resonance effect of the first superconducting bit circuit and the second superconducting bit circuit as zero.

16. The quantum computer of claim 15, wherein the controller comprises a bias circuit, and wherein the controller is further configured to adjust the frequency response curve based on a bias current or a bias voltage.

17. The quantum computer of claim 15, wherein the controller is configured to output a control signal, and wherein the coupler comprises:
an adjustable coupling circuit configured to adjust the frequency response curve based on the control signal;
a first fixed coupling circuit connected to the first superconducting bit circuit and the adjustable coupling circuit; and
a second fixed coupling circuit connected to the second superconducting bit circuit and the adjustable coupling circuit.

18. The quantum computer of claim 17, wherein the first fixed coupling circuit comprises a first capacitor, wherein the second fixed coupling circuit comprises a second capacitor, wherein the adjustable coupling circuit comprises a superconducting quantum interference device (SQUID) and a third capacitor, wherein the SQUID is connected in parallel to the third capacitor, and wherein the SQUID is configured to produce an equivalent inductance value that is adjustable using a circuit bias line.

19. The quantum computer of claim 18, wherein the adjustable coupling circuit comprises two ends and a capacitor, wherein each of the two ends is grounded using the capacitor, wherein a first end of the two ends is coupled to the first superconducting bit circuit using the first fixed coupling circuit, and wherein a second end of the two ends is coupled to the second superconducting bit circuit using the second fixed coupling circuit.

20. The quantum computer of claim 18, wherein the adjustable coupling circuit comprises two ends and a capacitor, wherein each of the two ends is grounded using the capacitor, and wherein one end of the two ends is coupled to the first superconducting bit circuit using the first fixed coupling circuit and to the second superconducting bit circuit using the second fixed coupling circuit.
